(19) United States
(12) Patent Application Publication
(10) Pub. No.: US 2012/0012049 A1
(43) Pub. Date: Jan. 19, 2012

(54) HVPE CHAMBER

(76) Inventors: Wei-Yung Hsu, San Jose, CA (US); Donald J.K. Olgado, Palo Alto, CA (US); Anzhong Chang, San Jose, CA (US)

(21) Appl. No.: 13/184,390

(22) Filed: Jul. 15, 2011

Related U.S. Application Data
(60) Provisional application No. 61/364,805, filed on Jul. 16, 2010.

(51) Int. Cl. C30B 25/08; C30B 35/00; C30B 25/12

(52) U.S. Cl. 117/98; 118/730

(57) ABSTRACT

Embodiments disclosed herein generally relate to an HVPE chamber. The chamber may have one or more precursor sources coupled thereto. For example, a gallium source and a separate aluminum source may be coupled to the processing chamber to permit gallium nitride and aluminum nitride to be separately deposited onto a substrate in the same processing chamber. The nitrogen may be introduced to the processing chamber at a separate location from the precursors and at a lower temperature. The chamber has a truncated box shape formed by a curved cover which improves the flow of the nitrogen and precursor gases and the uniformity of the film deposition.

### CROSS-REFERENCE TO RELATED APPLICATIONS

This application claims benefit of U.S. provisional patent application Ser. No. 61/364,805, filed Jul. 16, 2010, which is herein incorporated by reference.

### BACKGROUND OF THE INVENTION

1. Field of the Invention

Embodiments of the present invention generally relate to a hydride vapor phase epitaxy (HVPE) chamber.

2. Description of the Related Art

Group-III nitride semiconductors are finding greater importance in the development and fabrication of short wavelength light emitting diodes (LEDs), laser diodes (LDs), and electronic devices including high power, high frequency, and high temperature transistors and integrated circuits. One method that has been used to deposit Group-III nitrides is HVPE. In HVPE, a hydride gas reacts with the Group-III metal which then reacts with a nitrogen precursor to form the Group-III metal nitride.

FIG. 1A is an isometric schematic view of a prior art HVPE apparatus 100. The apparatus 100 is a cylindrical chamber that includes a showerhead 102 at a first end thereof for introducing a nitrogen containing gas. The nitrogen containing gas flows into the chamber in the general direction shown by arrows 113. The nitrogen containing gas may comprise N₂, NH₃, or combinations thereof. In one embodiment, the nitrogen containing gas comprises a mixture of N₂ and NH₃ at a mix ratio of between about 1:10 to about 1:18 N₂:NH₃.

The apparatus 100 has an inlet tube 110 which is configured in the shape of a ring. The inlet tube 110 may be disposed proximate to and along the inside perimeter of a sidewall 116 of the apparatus 100 and may be positioned between the showerhead 102 and a wall 106 of the chamber 100 opposite the showerhead 102. The inlet tube 110 has holes or openings throughout its circumference (see, e.g., holes 112 and 114 in FIG. 1C) to allow the flow of gas from inside of the inlet tube 110 to the chamber volume (108 in FIG. 1B). The nitrogen containing gas reacts with a metal chloride gas. In one embodiment, the metal chloride gas comprises gallium chloride. In another embodiment, the metal chloride gas comprises aluminum chloride. The metal chloride gas may be delivered to the apparatus 100 through the inlet tube 110. In one embodiment, the metal chloride gas may be delivered to the apparatus 100 using a carrier gas. In one embodiment, the carrier gas comprises an inert gas. In another embodiment, the carrier gas comprises nitrogen.

The apparatus 100 may be exhausted through a bottom exhaust 103 that communicates with the processing area through pumping holes near the wall 106 of the chamber. A purge gas may be introduced to the chamber through a bottom purge (not shown). The purge gas may comprise an inert gas or the purge gas may comprise nitrogen. The purge gas may be introduced at a rate of between about 10 SLM and about 18 SLM. In operation, one or more substrates are positioned on a rotatable substrate carrier 111 near the wall 106 of the chamber and rotated during deposition. Rotatable substrate carrier 111 can be rotated using a motor mechanically coupled to a shaft (motor and shaft shown schematically as 121 in FIG. 1B) which may rotate rotatable substrate carrier 111 clockwise or counterclockwise. Lamps or embedded heaters (not shown) maintain the rotatable substrate support 111, and hence any substrates thereon, heated. As shown in the prior art apparatus 100 of FIG. 1A, the showerhead 102 is parallel to the rotatable substrate carrier 111 and overlies all of the substrates on the rotatable substrate carrier 111.

FIG. 1B is a partial schematic view of the HVPE apparatus shown in FIG. 1A. As can be seen from FIG. 1B, the gas may be introduced though multiple locations. The nitrogen containing gas may be introduced from the top of the chamber 100 through the showerhead 102 whereas the metal chloride may be delivered near the middle of the chamber around the edges through the holes in the inlet tube 110. The direction in which the gas is introduced from the inlet tube 110 in the middle area may have an effect on the gas flow within the chamber 100 because the nitrogen containing gas is flowing from the showerhead towards the rotatable substrate carrier 111, as shown by arrows 113 in FIG. 1A. FIG. 1C is a cross-sectional view of the inlet tube 110 of FIG. 1B. As shown in FIG. 1C, the metal chloride may be introduced in a direction generally perpendicular to the chamber wall 116 as shown by arrow 118. Alternatively, the metal chloride may be introduced in a direction that is generally in line with the flow of the nitrogen gas from the showerhead and substantially parallel to the chamber walls, as shown by arrow 120.

FIG. 1D shows the gas flow of FIG. 1C when gas is introduced through gas inlets 112. FIG. 1E is a top view of the gas flow of FIG. 1D. FIG. 1F shows the gas flow of FIG. 1C when gas is introduced through gas inlets 114. FIG. 1G is a top view of the gas flow of FIG. 1F. As can be seen from FIG. 1D, the gas flow into the chamber creates a generally higher concentration of metal nitride near the center of the chamber which results in a center high deposition as shown in FIG. 1E. As can be seen from FIG. 1F, the gas flow into the chamber creates a generally higher concentration of metal nitride near the edge of the chamber which results in an edge high deposition as shown in FIG. 1G. Thus, the direction of gas flow within the chamber greatly affects the deposition upon the substrate during a deposition process.

As the demand for LEDs, LDs, transistors, and integrated circuits increases, the uniformity of depositing the Group-III metal nitride takes on greater importance. Therefore, there is a need in the art for an improved HVPE deposition method and an HVPE apparatus.

### SUMMARY OF THE INVENTION

Embodiments disclosed herein generally relate to an HVPE chamber. The chamber may have one or more precursor sources coupled thereto. When two separate precursor sources are coupled thereto, two separate layers may be deposited. For example, a gallium source and a separate aluminum source may be coupled to the processing chamber to permit both, or either of, gallium nitride and aluminum nitride to be separately deposited onto a substrate in the same processing chamber where a nitrogen source gas is also present. In one embodiment, five precursor sources may be coupled to the chamber. Such precursor sources are capable of dispensing precursors such as gallium, indium, aluminum, silicon, and magnesium. When the precursors are used to form a nitrogen containing compound, a nitrogen containing gas such as NH₃ may be used to provide the nitrogen in the nitride compound. The nitrogen may be introduced to the processing chamber at a separate location from the precursors and at a lower temperature. The chamber may be configured geometrically so that the precursor and the reactive gas may be introduced to the chamber separately to avoid control reaction of the components.

In one embodiment, an apparatus is disclosed. The apparatus comprises a base, a first end wall extending generally perpendicular thereto at one end of the base and a second end wall extending generally perpendicular thereto at an opposite side of the base, the second end wall generally parallel to the first end wall, but extending a shorter distance from the base than does the first end wall, and a showerhead extending from the end of the first end wall, at a side thereof opposite to the base, and in the direction of the second end wall and generally parallel to the base, for a distance less than the span of the base. A first side wall and a second side wall which are opposite from one another, extend perpendicularly up from the base, connect to, at locations along the sides of, the first and second end walls and the showerhead, and have a generally curved side, extending from the end of the second end wall opposite to the base to the end of the showerhead at its furthest position from the first end wall. A curved cover wall extends between the two side walls at the generally curved sides and from the side of the second end wall furthest from the base to the side of the showerhead furthest from the first end wall. In this manner a vacuum sealable, non-rectangular but regularly shaped chamber volume is formed for processing of substrates or other objects therein. A rotatable substrate support is located generally parallel to and spaced from the base, and faces the showerhead, but only a portion thereof is located directly below the showerhead. One or more gas introduction tubes extending parallel to and across the curved cover wall in a direction generally perpendicular to, and spanning the length between, the two side walls. The gas introduction tubes may be located inside of, or exterior to the chamber volume, but the interior volume of the tubes is communicable with the interior of the chamber volume, or may be a channel extending across the curved cover wall and having holes, slits, or other fluid communication ports, extending to the chamber volume.

In another embodiment, a method of operating a processing chamber is provided. The method comprises the step of introducing at least one nitrogen containing gas into a processing chamber comprising a chamber body. The chamber body includes a base, a first end wall extending perpendicular thereto at one side of the base, and a second end wall extending perpendicular thereto at an opposite side of the base, the second end wall parallel to the first end wall, but extending a shorter distance from the base than does the first end wall. The chamber body also comprises a showerhead extending from the end of the first end wall at a side thereof opposite to the base, and in the direction of the second end wall and parallel to the base, for a distance less than the span of the base. A first side wall and a second side wall which are opposite to one another extend perpendicularly up from the base, connect along the sides thereof to the sides of the first and second end walls and the showerhead, and have a generally curved side, extending from the end of the second side wall opposite to the base to the end of the showerhead at its furthest position from the first side wall. The chamber body also comprises a curved cover wall extending between the first side wall and the second side wall at the curved sides and from the side of the second end wall furthest from the base to the side of the showerhead furthest from the first end wall, a rotatable substrate support located generally parallel to and spaced from the base, and facing the showerhead, and one or more gas introduction tubes extending parallel to and across the curved cover wall in a direction generally perpendicular to, and spanning the length between, the two sidewalls. The at least one nitrogen containing gas is introduced through the gas distribution showerhead. The method further comprises the step of introducing at least one metal chloride gas through the one or more gas introduction tubes such that the nitrogen containing gas and the at least one metal chloride gas flow towards the rotatable substrate carrier.

In another embodiment, a method of operating a processing chamber is provided. The method comprises the step of introducing at least one nitrogen containing gas and at least one metal chloride gas into a processing chamber comprising a chamber body. The chamber body includes a base, a first end wall extending perpendicular thereto at one side of the base, and a second end wall extending perpendicular thereto at an opposite side of the base, the second end wall parallel to the first end wall, but extending a shorter distance from the base than does the first end wall. The chamber body also includes a showerhead extending from the end of the first end wall at a side thereof opposite to the base, and in the direction of the second end wall and parallel to the base, for a distance less than the span of the base. A first side wall and a second side wall, which are opposite to one another, extend perpendicularly up from the base, connect along the sides thereof to the sides of the first and second end walls and the showerhead, and have a generally curved side, extending from the end of the second side wall opposite to the base to the end of the showerhead at its furthest position from the first side wall. The chamber body further comprises a curved cover wall extending between the first side wall and the second side wall at the curved sides and from the side of the second end wall furthest from the base to the side of the showerhead furthest from the first end wall, a rotatable substrate support located generally parallel to and spaced from the base, and facing the showerhead, and one or more gas introduction tubes extending parallel to and across the curved cover wall in a direction generally perpendicular to, and spanning the length between, the two sidewalls, wherein the at least one nitrogen containing gas and the at least one metal chloride gas are introduced through the gas distribution showerhead, such that the nitrogen containing gas and the at least one metal chloride gas flow towards the rotatable substrate carrier.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is an isometric schematic view of a prior art HVPE processing chamber.

FIG. 1B is a partial schematic view of the HVPE apparatus shown in FIG. 1A.

FIG. 1C is a cross-sectional view of the inlet tube 110 of FIG. 1B.

FIG. 1D shows the gas flow of FIG. 1A when gas is introduced through gas inlets 112.

FIG. 1E is a top view of the gas flow of FIG. 1D.

FIG. 1F shows the gas flow of FIG. 1A when gas is introduced through gas inlets 114.

FIG. 1G is a top view of the gas flow of FIG. 1F.

FIG. 2A is a schematic isometric view of the HVPE apparatus according to one embodiment.

FIG. 2B shows the gas flow for the apparatus of FIG. 2A according to one embodiment.

FIG. 2C shows the gas flow for the apparatus of FIG. 2A according to another embodiment.

FIG. 2D is a graph showing the deposition rate for a film deposited using the apparatus of FIG. 2A.

FIG. 2E shows the mole fraction contours for gallium chloride in the apparatus of FIG. 2A.

FIG. 2F shows the gas flow for the apparatus of FIG. 2A according to one embodiment.

FIG. 2G shows the gas flow for the apparatus of FIG. 2A according to another embodiment.

FIG. 2H is a graph showing the deposition rate for a film deposited using the apparatus of FIG. 2A.

FIG. 2I shows the mole fraction contours for gallium chloride in the apparatus of FIG. 2A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally relate to an HVPE chamber for the deposition therein of one or more film layers on a substrate. The chamber may have one or more precursor sources coupled thereto. When two separate precursor sources are coupled thereto, two separate layers may be deposited on a substrate located therein. For example, a gallium source and a separate aluminum source may be coupled to the processing chamber to permit gallium nitride and aluminum nitride to be separately deposited onto a substrate in the same processing chamber. In one embodiment, five precursor sources may be coupled to the chamber. Such precursor sources are capable of dispensing precursors such as gallium, indium, aluminum, silicon, and magnesium. When the precursors are used to form a nitrogen containing compound, a nitrogen containing gas such as NH₃ may also be introduced into the chamber. The nitrogen containing gas may be introduced to the processing chamber at a separate location from the location where the precursors are introduced, and at a lower temperature than the precursors. The geometry of the chamber may be set such that the precursor and the reactive gas are introduced to the chamber separately to avoid mixing thereof prior to entry into the chamber. The shape of the chamber, which will be described below, unexpectedly results in an even distribution of processing gas above the substrate.

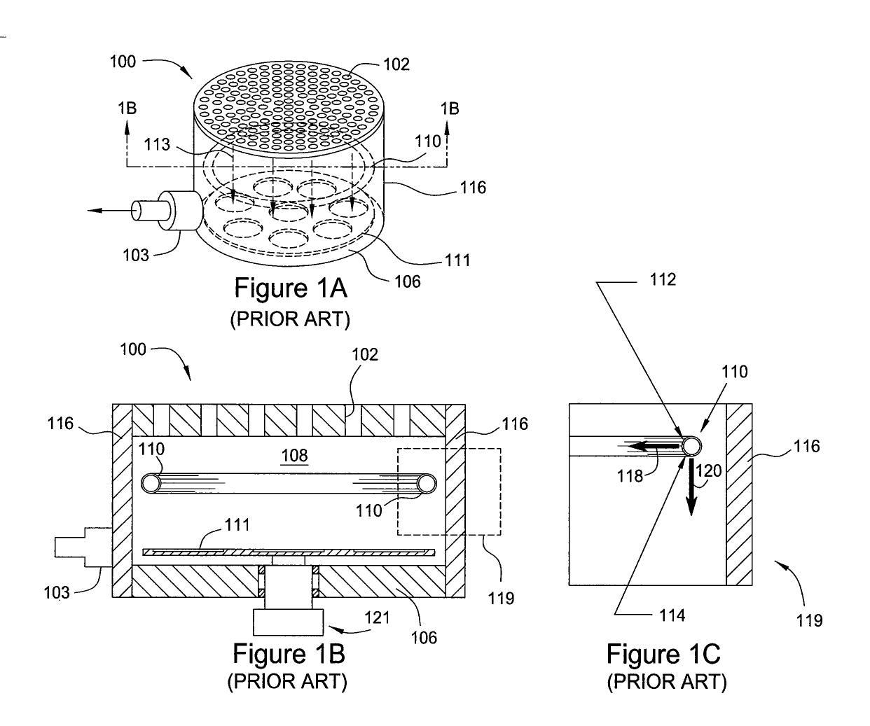

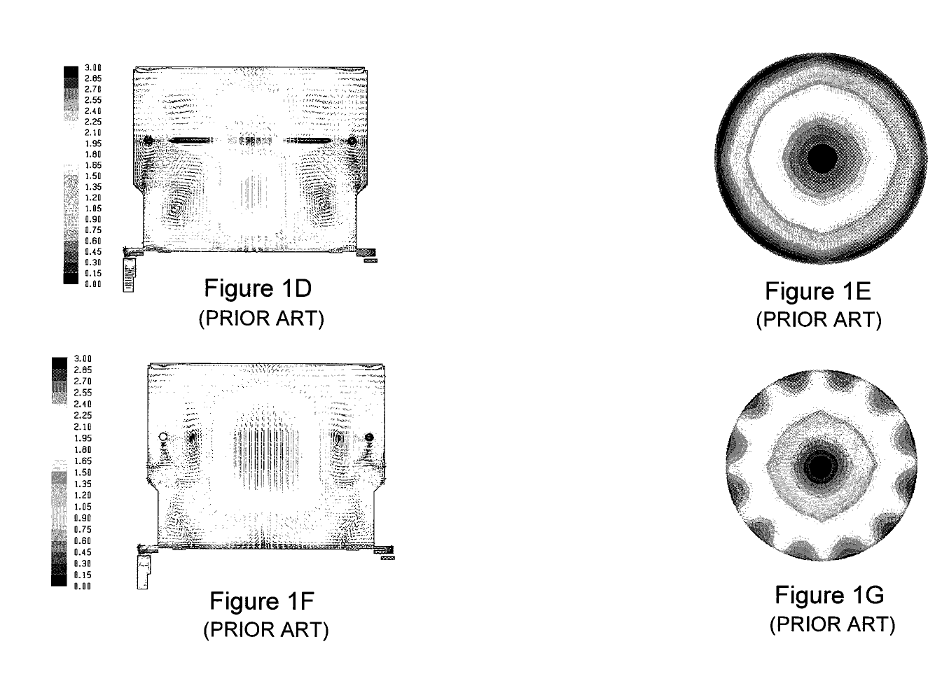

It has surprisingly been found that a processing chamber that has a curved wall that creates a truncated box shape may more evenly distribute the reactive gases within the chamber in comparison to known chambers such as shown in FIGS. 1A-1E.

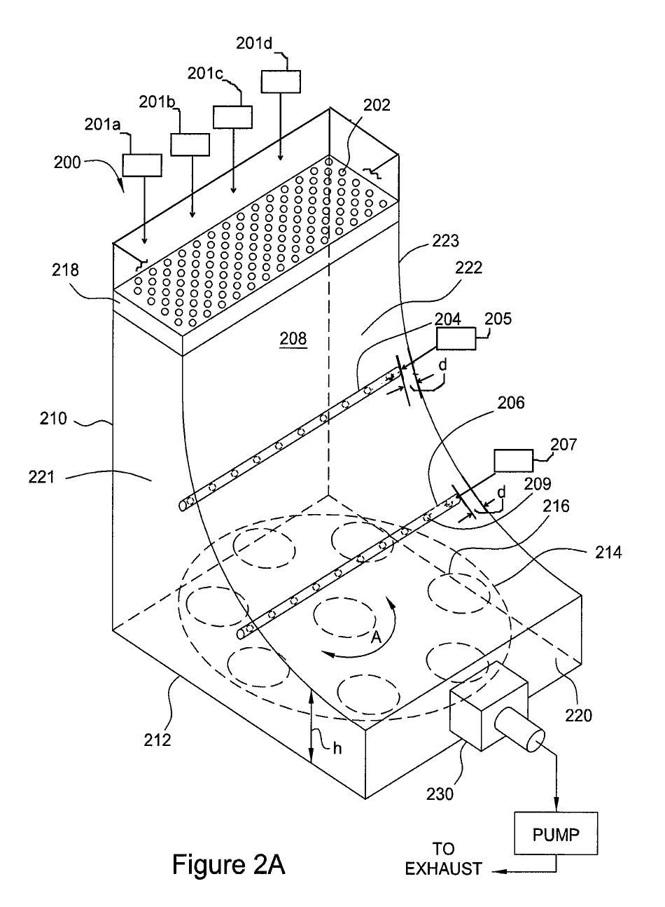

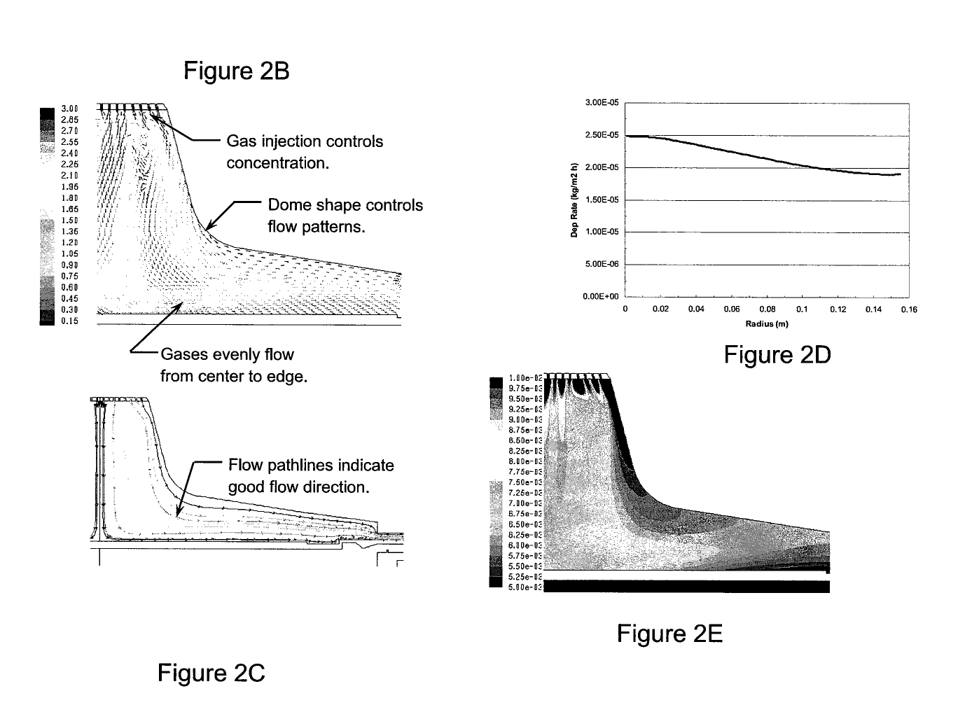

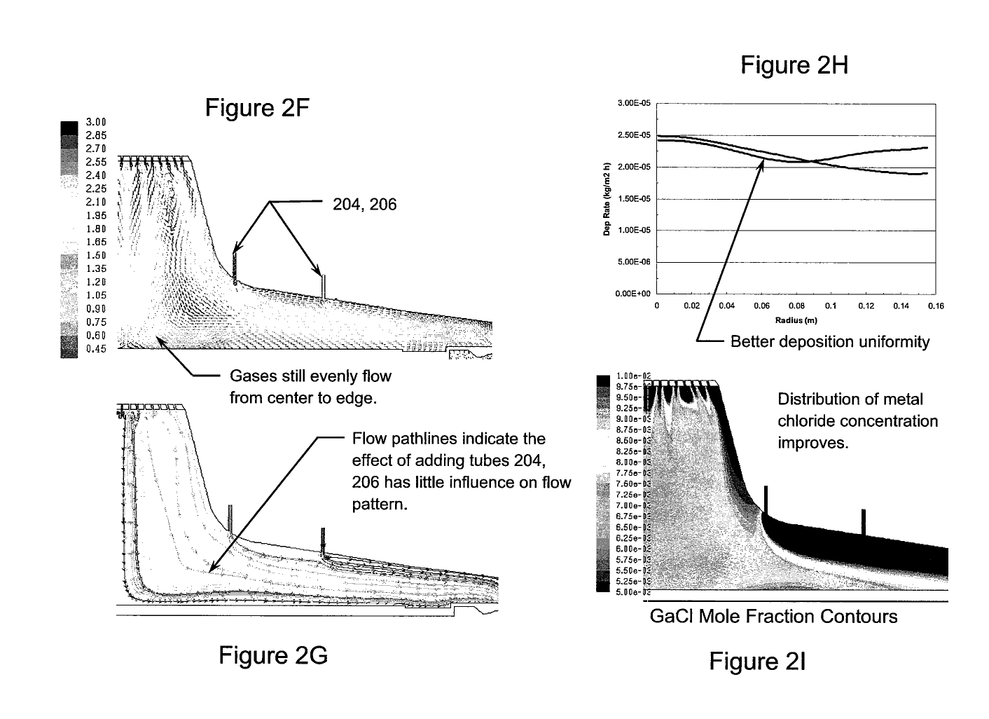

FIG. 2A is a schematic isometric view of the HVPE apparatus 200 according to one embodiment. The apparatus 200 includes a showerhead 218 having a plurality of openings 202 therethrough to permit the nitrogen containing gas to enter the chamber. The apparatus 200 also has a first end wall 210 that extends to a first height above a base 212. The end wall 210 is perpendicular to base 212. The base 212 is parallel and opposite to the showerhead 218. (Although referred to herein as base 212, it should be noted that embodiments of the processing chamber described herein are not limited to a configuration in which the showerhead faces down. Other embodiments such as having a configuration wherein the showerhead faces up are also possible.) A second end wall 220 is also present. The second end wall 220 is parallel to the first end wall 210, but extends perpendicular to the base 212 and to a height lower than the first end wall 210. The showerhead 218 extends out from the first end wall 210 for a distance which is less than the span of the base 212. The difference in height between the first end wall 210 and the second end wall 220 and the difference in length between the base 212 and the showerhead 218 allows a curved cover wall 208 to extend from the showerhead 218 to the second end wall 220. The curved cover wall 208 may form a curvature 223 such that the height h of the apparatus 200 remains the same in a direction from the first end wall 210 to the second end wall 220 for the extent of the length of the showerhead 218, but decreases in a direction past the showerhead 218 towards the second end wall 220. The curved cover wall 208 creates a truncated box shape. A first side wall 221 and a second side wall 222 complete the enclosure in the chamber and support the lateral sides of the curved cover wall 208, the showerhead 218, the first end wall 210, the second end wall 220, and the base 212. In the embodiment shown in FIG. 2A, the first side wall 221 and the second side wall 222 each have five edges. As explained above, for each of the first side wall 221 and the second side wall 222, the curvature 223 is not connected to the base 212, the first end wall 210, the second end wall 220 or the showerhead 218. The distance that the showerhead 218 extends from the first end wall 210 and the height of second end wall 220 help determine the shape of curvature 223. The curvature 223 formed by the curved cover wall 208 affects the flow of gases from the showerhead 218, and its shape may accordingly be modified to improve gas flow characteristics.

One or more gas introduction tubes may extend from the first side wall 221 to the second side wall 222 with each gas introduction tube being proximate the curved cover wall 208. Each end of the one or more gas introduction tubes may connect to a gas supply (see, e.g., 205 and 207 in FIG. 2A). The one or more gas introduction tubes extend parallel to and across the curved cover wall 208 in a direction generally perpendicular to, and spanning the length between, the first side wall 221 and the second side wall 222. In some embodiments, the gas introduction tubes may be located inside of the chamber volume, and in other embodiments, the gas introduction tubes may be located exterior to the chamber volume, but the interior volume of the tubes is communicable with the interior of the chamber volume, or may be a channel extending across the curved cover wall and having holes, slits, or other fluid communication ports, extending to the chamber volume.

The embodiment shown in FIG. 2A includes a first gas introduction tube 204 and a second gas introduction tube 206 each connected to gas supply 205 and gas supply 207, respectively. As shown in FIG. 2A, the first gas introduction tube 204 and the second gas introduction tube 206 may be straight and be disposed within the processing volume inside apparatus 200 a distance d from the curved cover wall 208. The distance d may be the same for each gas introduction tube (as shown in FIG. 2A) or it may vary from one gas introduction tube to the next. The larger d is, the further the gas introduction tube is from the curved cover wall 208.

In the HVPE process, metal chloride gas may be introduced through one or more openings 207, 209 that are present in each gas introduction tube 204, 206. In some embodiments, the one or more openings 207, 209 may be spaced evenly along each gas introduction tube 204, 206. The one or more openings 207, 209 may be located along a surface of the gas introduction tube 204, 206 facing away from the inside surface of the curved cover wall 208. In other embodiments, spacing and location of the openings 207, 209 on the gas introduction tubes 204, 206 may be varied depending on gas flow characteristics. Similarly, spacing and location o f the gas introduction tubes 204, 206 may also be varied in order to improve gas flow characteristics. For example, when one gas introduction tube is present, the gas introduction tube may be disposed proximate the midpoint of the length of the curved cover wall 208. As shown in the embodiment of FIG. 2A, when two gas introduction tubes 204, 206 are present, each gas introduction tube 204, 206 may be disposed at locations proximate about one-third of the length of the curved cover wall 208 from each end of the curved cover wall 208. The one or more gas introduction tubes are vertically located between the showerhead 218 and the rotating substrate carrier 214.

One or more substrates 216 (shown in shadow) may be disposed on a rotating substrate carrier 214 (shown in shadow) which is disposed inside the apparatus 200 and positioned proximate the base 212. The substrate carrier 214 may rotate in either direction as shown by arrow “A” by a motor mechanically coupled to a shaft (not shown). The apparatus 200 may be exhausted through a bottom exhaust 230 that communicates with the processing area through at least one pumping hole at the second end wall 220 of the chamber. A purge gas may be introduced to the chamber through a bottom purge (not shown). In one embodiment, the purge gas may comprise an inert gas. In another embodiment, the purge gas may comprise nitrogen.

The showerhead 218 extends directly over only part of the rotating substrate carrier 214. As shown schematically in FIG. 2A, gas sources 201a, 201b, 201c and 201d may feed gases into a plenum formed above the showerhead 218. Each gas source may feed a difference precursor gas to the chamber. Because of the curved cover wall 208, the substrates 216 will continuously move from a position close to the curved cover wall 208 to a position directly under the showerhead 218 as the rotating substrate carrier 214 rotates. Naturally, one of ordinary skill in the art would expect the gas to be unevenly distributed within the chamber with the majority of the gas being adjacent the substrates 216 as they are directly under the showerhead 218. However, it has been surprisingly found that the gas will be evenly distributed within the chamber.

FIG. 2B shows the gas flow for the apparatus of FIG. 2A according to one embodiment. FIG. 2C shows the gas flow for the apparatus of FIG. 2A according to the embodiment used for FIG. 2B. FIG. 2D is a graph showing the deposition rate for a film deposited using the apparatus of FIG. 2A. FIG. 2E shows the mole fraction contours for gallium chloride in the apparatus of FIG. 2A. For FIGS. 2B-2E, the modeling shows gas introduced through the showerhead 218 only. The gas injection through the showerhead 218 controls the concentration of the gas. The curved shape caused by the curved cover wall 208 controls the flow patterns of the gas.

As shown in FIG. 2B, the gases flow evenly from the center to the edge of the chamber bottom. The gases travel generally downward from the showerhead 218, but because of the dome shape, generally flow parallel to the bottom surface of the chamber. Thus, the gases are expected to flow generally parallel to the surface of the substrates 216 rotating on the substrate carrier 214. FIG. 2C confirms the direction of flow. The flow pathlines show how the gas introduced from the showerhead 218 flows within the chamber. In the embodiment shown in FIGS. 2B-2E, the gas introduced included NH₃ at 15 SLM and N₂ at 9 SLM, and GaCl at 300 sccm and N₂ at 16 SLM. The chamber bottom was purged with nitrogen at 15 SLM. The chamber pressure was maintained at 250 Torr while the substrate temperature was maintained at 1040 degrees Celsius. The substrates were rotated at 20 RPM. The depletion of the gases causes the deposition rate to drop along the substrate surface as shown in FIG. 2D. The metal chloride (in this case, GaCl) concentration drops along the substrate due to the depletion caused by reaction of the metal chloride with the nitrogen. FIG. 2E shows the metal chloride mole fraction contours.

FIG. 2F shows the gas flow for the apparatus of FIG. 2A according to an embodiment wherein gas is introduced through gas introduction tubes 204 and 206. FIG. 2G shows the gas flow for the apparatus of FIG. 2A according to the embodiment used for FIG. 2F. FIG. 2H is a graph showing the deposition rate for a film deposited using the apparatus of FIG. 2A according to the embodiment used for FIG. 2F. FIG. 2I shows the mole fraction contours for gallium chloride in the apparatus of FIG. 2A according to the embodiment used for FIG. 2F. In the embodiment shown in FIGS. 2F-2I, the nitrogen containing gas is introduced through the showerhead 218, and metal chloride is introduced through the gas introduction tubes 204, 206. In the embodiment shown in FIGS. 2F-2I, the gas introduced through the showerhead 218 included NH₃ at 15 SLM and N₂ at 9 SLM, and the gas introduced through the gas introduction tubes 204, 206 included GaCl at 300 sccm and N₂ at 16 SLM. The chamber bottom was purged with nitrogen at 15 SLM. The chamber pressure was maintained at 250 Torr while the substrate temperature was maintained at 1040 degrees Celsius. The substrates were rotated at 20 RPM. The gases evenly flowed from the center to the edge within the chamber even though the metal chloride was introduced through the gas introduction tubes 204, 206 along the curved wall 208. The flow pathlines shown in FIG. 2G indicate that adding the gas introduction tubes 204, 206 has little influence on the flow pattern within the chamber. However, there is a better deposition uniformity as shown in FIG. 2H and a better distribution of the metal chloride concentration as shown in FIG. 2I.

By utilizing a chamber having a curved cover wall, the distribution of processing gases within an HVPE chamber may be unexpectedly improved. The chamber of the present invention obtains a gas flow in which the gases will flow substantially parallel to the bottom of the chamber while the substrates are disposed on a rotating substrate carrier. Because the gases are induced to flow substantially parallel to the chamber bottom, the distribution of the gases is improved, which improves deposition uniformity.

While the foregoing is directed to embodiments of the present invention, other and further embodiments of the invention may be devised without departing from the basic scope thereof, and the scope thereof is determined by the claims that follow.

1. An apparatus, comprising:
a base;
a first end wall extending perpendicular thereto at one side of the base;
a second end wall extending perpendicular thereto at an opposite side of the base, the second end wall parallel to the first end wall, but extending a shorter distance from the base than does the first end wall;
a showerhead extending from the end of the first end wall at a side thereof opposite to the base, and in the direction of the second end wall and parallel to the base, for a distance less than the span of the base;
a first side wall and a second side wall, wherein the first side wall and the second side wall are opposite to one another, extend perpendicularly up from the base, connect along the sides thereof to the sides of the first and second end walls and the showerhead, and have a curved side, extending from the end of the second side wall opposite to the base to the end of the showerhead at its furthest position from the first side wall;
a curved cover wall extending between the first side wall and the second side wall at the curved sides and from the side of the second end wall furthest from the base to the side of the showerhead furthest from the first end wall;
a rotatable substrate support located generally parallel to and spaced from the base, and facing the showerhead; and
one or more gas introduction tubes extending parallel to and across the curved cover wall in a direction generally perpendicular to, and spanning the length between, the two sidewalls.

2. The apparatus of claim 1, wherein a portion of the rotatable substrate support is not located directly below the showerhead.

3. The apparatus of claim 1, wherein the apparatus comprises two gas introduction tubes.

4. The apparatus of claim 3, wherein one gas introduction tube is located about one third of the length of the curved cover wall down the curved cover wall and wherein the second gas introduction tube is located about two thirds of the length of the curved cover wall down the curved cover wall.

5. The apparatus of claim 1, wherein the apparatus comprises one gas introduction tube located about halfway down the curved cover wall.

6. The apparatus of claim 1, further comprising an exhaust near the second end wall.

7. A method of operating a processing chamber, the method comprising:
introducing at least one nitrogen containing gas into a processing chamber comprising a chamber body having:
a base;
a first end wall extending perpendicular thereto at one side of the base;
a second end wall extending perpendicular thereto at an opposite side of the base, the second end wall parallel to the first end wall, but extending a shorter distance from the base than does the first end wall;
a showerhead extending from the end of the first end wall at a side thereof opposite to the base, and in the direction of the second end wall and parallel to the base, for a distance less than the span of the base;
a first side wall and a second side wall, wherein the first side wall and the second side wall are opposite to one another, extend perpendicularly up from the base, connect along the sides thereof to the sides of the first and second end walls and the showerhead, and have a curved side, extending from the end of the second side wall opposite to the base to the end of the showerhead at its furthest position from the first side wall;
a curved cover wall extending between the first side wall and the second side wall at the curved sides and from the side of the second end wall furthest from the base to the side of the showerhead furthest from the first end wall;
a rotatable substrate support located generally parallel to and spaced from the base, and facing the showerhead; and
one or more gas introduction tubes extending parallel to and across the curved cover wall in a direction generally perpendicular to, and spanning the length between, the two sidewalls, wherein the at least one nitrogen containing gas is introduced through the gas distribution showerhead; and
introducing at least one metal chloride gas through the one or more gas introduction tubes such that the nitrogen containing gas and the at least one metal chloride gas flow towards the rotatable substrate carrier.

8. The method of claim 7, wherein the at least one nitrogen-containing gas is NH₃ or N₂.

9. The method of claim 7, wherein the at least one metal chloride gas is GaCl or AlCl₃.

10. The method of claim 7, wherein the pressure within processing chamber is about 250 Torr and the rotatable substrate carrier rotates at 20 RPM.

11. The method of claim 7, further comprising purging a bottom of the processing chamber with nitrogen (N₂) gas.

12. The method of claim 7, wherein the rotatable substrate carrier maintains substrates at a temperature of about 1040 degrees Celsius.

13. The method of claim 7, wherein the at least one metal chloride gas is introduced with a carrier gas.

14. A method of operating a processing chamber, the method comprising:
introducing at least one nitrogen containing gas and at least one metal chloride gas into a processing chamber comprising a chamber body having:
a base;
a first end wall extending perpendicular thereto at one side of the base;
a second end wall extending perpendicular thereto at an opposite side of the base, the second end wall parallel to the first end wall, but extending a shorter distance from the base than does the first end wall;
a showerhead extending from the end of the first end wall at a side thereof opposite to the base, and in the direction of the second end wall and parallel to the base, for a distance less than the span of the base;
a first side wall and a second side wall, wherein the first side wall and the second side wall are opposite to one another, extend perpendicularly up from the base, connect along the sides thereof to the sides of the first and second end walls and the showerhead, and have a curved side, extending from the end of the second side wall opposite to the base to the end of the showerhead at its furthest position from the first side wall;
a curved cover wall extending between the first side wall and the second side wall at the curved sides and from the side of the second end wall furthest from the base to the side of the showerhead furthest from the first end wall;
a rotatable substrate support located generally parallel to and spaced from the base, and facing the showerhead; and
one or more gas introduction tubes extending parallel to and across the curved cover wall in a direction generally perpendicular to, and spanning the length between, the two sidewalls; and, wherein the at least one nitrogen containing gas and the at least one metal chloride gas are introduced through the gas distribution showerhead, such that the nitrogen containing gas and the at least one metal chloride gas flow towards the rotatable substrate carrier.

15. The method of claim 14, wherein the at least one nitrogen-containing gas is NH₃ or N₂.

16. The method of claim 14, wherein the at least one metal chloride gas is GaCl or AlCl₃.

17. The method of claim 14, wherein the pressure within processing chamber is about 250 Torr and the rotatable substrate carrier rotates at 20 RPM.

18. The method of claim 14, further comprising purging a bottom of the processing chamber with nitrogen (N₂) gas.

19. The method of claim 14, wherein the rotatable substrate carrier maintains substrates at a temperature of about 1040 degrees Celsius.
